(19) United States
(12) Patent Application Publication
(10) Pub. No.: US 2008/0042742 A1
(43) Pub. Date: Feb. 21, 2008

(54) Distortion Nulling for Single-Ended High Dynamic Range RF Amplifier

(75) Inventors: Lloyd F. Linder, Agoura Hills, CA (US); Wais M. Ali, Long Beach, CA (US)

Correspondence Address: INTELLECTUAL PROPERTY LAW OFFICE OF JOEL VOELZKE, 24772 SADDLE PEAK ROAD, MALIBU, CA, 90265, US

(73) Assignee: TechnoConcepts, Inc., Van Nuys, CA (US)

(21) Appl. No.: 11/839,197

(22) Filed: Aug. 15, 2007

Related U.S. Application Data
(60) Provisional application No. 60/837,818, filed on Aug. 15, 2006.

(51) Int. Cl. G06G 7/26; H03F 3/04; H03F 3/16

(52) U.S. Cl. 327/562; 330/277; 330/296

(57) ABSTRACT

A wideband low noise amplifier (LNA) includes a correction circuit added to compensate for third order intermodulations. A version of the third order nonlinearities created in the main LNA is created in an auxiliary, low power scaled version of the LNA, phased appropriately using a current mirror, and subtracted from the main signal path by summing, thus providing a cancellation of the third order intermodulation (IM) terms in the main signal path leaving a signal remaining which is significantly more spectrally pure than the signal produced by the LNA before correction.

### CROSS-REFERENCE TO RELATED APPLICATIONS

This application claims priority from U.S. Provisional Patent Application No. 60/837,818 filed Aug. 15, 2006.

### BACKGROUND OF THE INVENTION

1. Field of the Invention

This invention relates to the field of signal amplifiers. More particularly, this invention relates to the field of single-ended high dynamic range amplifiers having distortion nulling.

2. Description of Related Art

There is a need in the industry for extending the dynamic range of existing low noise amplifier (LNA) architectures without degrading the noise figure (NF) or increasing the direct current (DC) power consumption. The existing LNA topologies' dynamic range is constrained by the physical limitations of the particular topology. The fine line, submicron geometries of present day integrated circuit (IC) processes allow circuit designers to take advantage of the available bandwidth of these technologies to resultantly create new novel circuit solutions at radio frequency (RF) frequencies, that were previously not feasible as a result of device F_{T}s, and allow the possibility for enhancing the performance of the existing topologies.

### SUMMARY OF THE INVENTION

According to the present invention, a version of the third order nonlinearities created in the main LNA is first created in an auxiliary scaled version of the LNA, then phased appropriately and subtracted from the main signal path by summing, thus providing a cancellation of the third order intermodulation (IM) terms in the main signal path leaving a spectrally pure signal remaining. This allows the LNA to extend the existing achievable dynamic range. Additionally, the scaled version of the LNA contributes minimally to the NF of the uncorrected LNA. The scaled version of the LNA dissipates only a small fraction of the DC power dissipated in the main LNA. Thus, the overall dynamic range of the LNA is extended without impacting other nominal performance parameters for the circuit.

Several different embodiments of LNA circuits that implement the single ended intermodulation distortion nulling of the present invention are disclosed. In each embodiment the circuit is composed of a main amplifier stage and an IM cancellation stage.

The first and second embodiments apply the distortion nulling of the present invention to wideband amplifiers having common source (or common emitter) architectures. The first embodiment incorporates NPN bipolar transistors in a common emitter arrangement. The second embodiment uses CMOS transistors in a common source arrangement. Both designs are single ended amplifiers customized for low noise performance. The IM cancellation circuit in both designs will produce and inject an in-phase signal into the main amplifier. This signal current of the auxiliary LNA will have low level fundamental tones, but will have third order terms which should be in the same order of magnitude as the main amplifier stage. This summation of the main signal current and the injected signal current will produce a subtraction of IM terms which will result in improved intermodulation distortion. This will be accomplished without a significant reduction in the main signal current. Also, there will not be a significant increase in the overall noise performance or DC power consumption.

Additional embodiments apply the distortion nulling concept to tuned amplifiers, and to common gate (or common base) tuned amplifiers.

Exemplary embodiments of the invention will be further described below with reference to the drawings, in which like numbers refer to like parts.

### BRIEF DESCRIPTION OF THE DRAWINGS

FIG. 1 is a prior art NPN/BiCMOS LNA;

FIG. 2 is a prior art CMOS LNA;

FIG. 3 is block diagram of the distortion nulling concept according to the present invention;

FIG. 4 is a NPN/BiCMOS LNA with distortion nulling according to the present invention;

FIG. 5 is a CMOS LNA with distortion nulling according to the present invention;

FIG. 6 is a plot of a simulation result showing the performance of the prior art CMOS LNA of FIG. 2;

FIG. 7 is a plot of a simulation result showing the performance of the CMOS LNA of FIG. 5 according to the present invention;

FIG. 8 is a prior art tuned CMOS LNA;

FIG. 9 is a tuned CMOS LNA with distortion nulling according to the present invention;

FIG. 10 is a prior art common gate CMOS LNA;

FIG. 11 is a common gate CMOS LNA with distortion nulling according to the present invention;

FIG. 12 is a prior art inductively degenerated bipolar LNA;

FIG. 13 is a schematic of a tuned bipolar LNA with distortion nulling and process variation compensation according to the present invention;

FIG. 14 is a plot of a simulation result of the circuit of FIG. 13, showing before and after trim current for a nominal process;

FIG. 15 is a plot of a simulation result of the circuit of FIG. 13 showing OIP3 versus DAC1 trim current for a slow process; and

FIG. 16 is a simulation result showing the noise figure for a nominal process for the circuit of FIG. 13.

### DETAILED DESCRIPTION OF THE PREFERRED EMBODIMENTS

Intermodulation (IM) is a result of extra product terms produced from the main amplifier signal. For example, when a signal having frequency components f1 and f2 is applied to an amplifier, undesired product terms such as 2f1, 2f2, f1+f2 are produced. These product terms degrade the quality of the signal being amplified. This degradation is referred to as intermodulation distortion, and is related to the single tone third harmonic and the DC third order nonlinearity of the device. The most important products to consider when analyzing third order intermodulation distortion are the products located at 2f1-f2 and 2f2-f1. These terms are the most important since they are the closest to the fundamental tones (f1, f2). The IM cancellation circuits of the present invention decrease the IM tones at frequencies 2f1-f2 and 2f2-f1, essentially nulling these terms out in the main signal path. In a recent publication entitled “A +10 dBm IIP3 SiGe Mixer With IM3 Cancellation Technique”, by S. Otaka, M. Ashida, M. Ishii, and T. Itakura, IEEE Journal of Solid State Circuits, Vol. 39, No. 12, December 2004, IM cancellation purportedly was achieved in bipolar differential circuits. However, in designs with ultra low noise performance, such as LNAs that interface to antennas or channel select filters for receivers, single ended amplifiers are preferred in order to achieve the lowest possible input noise. The consequence of using a single ended amplifier is that differential IM cancellation techniques cannot be used to improve distortion. The differential cancellation approach, when applied to a single-ended topology requires single-ended to differential conversion. The resultant architecture causes significant gain errors in the process, does not track well over process and temperature, and thus the error correction is not very effective. Single ended IM cancellation circuits are disclosed herein in order to improve distortion while maintaining low input noise and low DC power.

I. Wideband Amplifiers

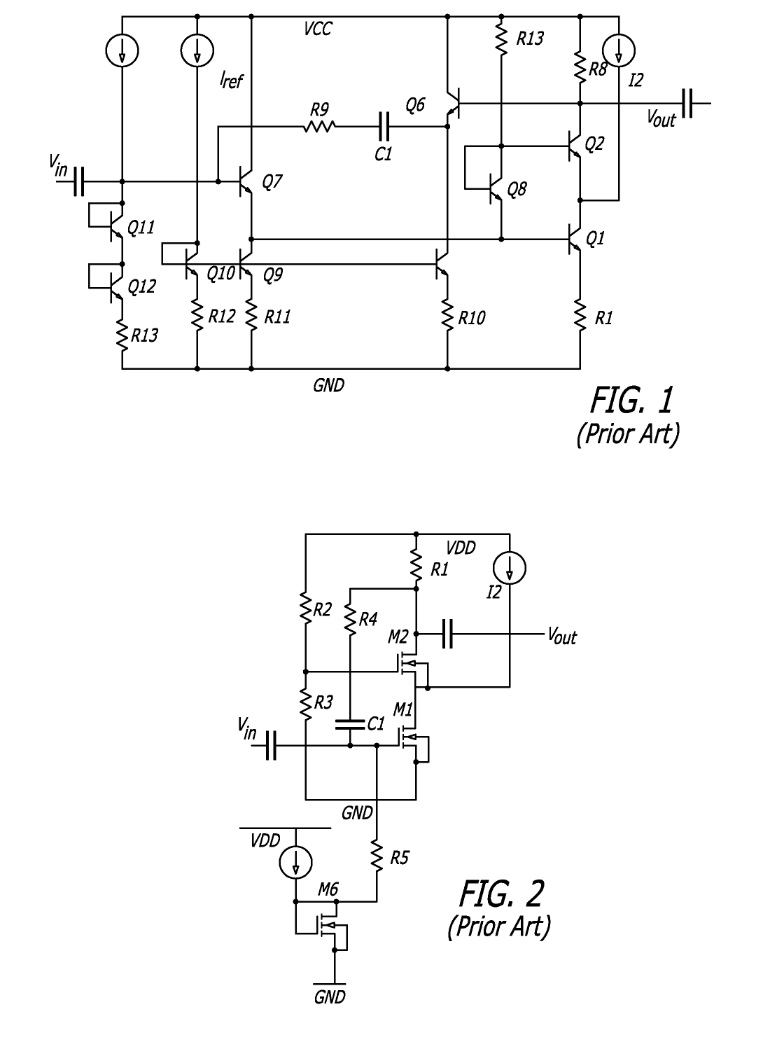

Prior art bipolar/BiCMOS LNA and CMOS LNA amplifiers shown in FIGS. 1 and 2, respectively. For existing LNA topologies, the two tone IM distortion can be shown to be related to the DC third order nonlinearity of the device. For the example of an NPN LNA in FIG. 1, the third order nonlinearity of a bipolar device can be described classically using a Taylor series expansion of the I-V characteristic. The third order nonlinear signal current for the bipolar device is:

I_{NL3}=(G_{M})(V_{T})/(Δi/I)³

where
G_{M} is the transconductance of the device=I/V_{T},
V_{T} is the thermal voltage for the device,
Δi is the signal current in the device, and
I is the DC bias current in the device.

Based on the above equations, for a given output signal current, the only way to reduce the third order nonlinearities' contribution to the output signal is to increase the DC current I. This would cause an increase in DC power consumption, and therefore is not a desirable solution to the problem.

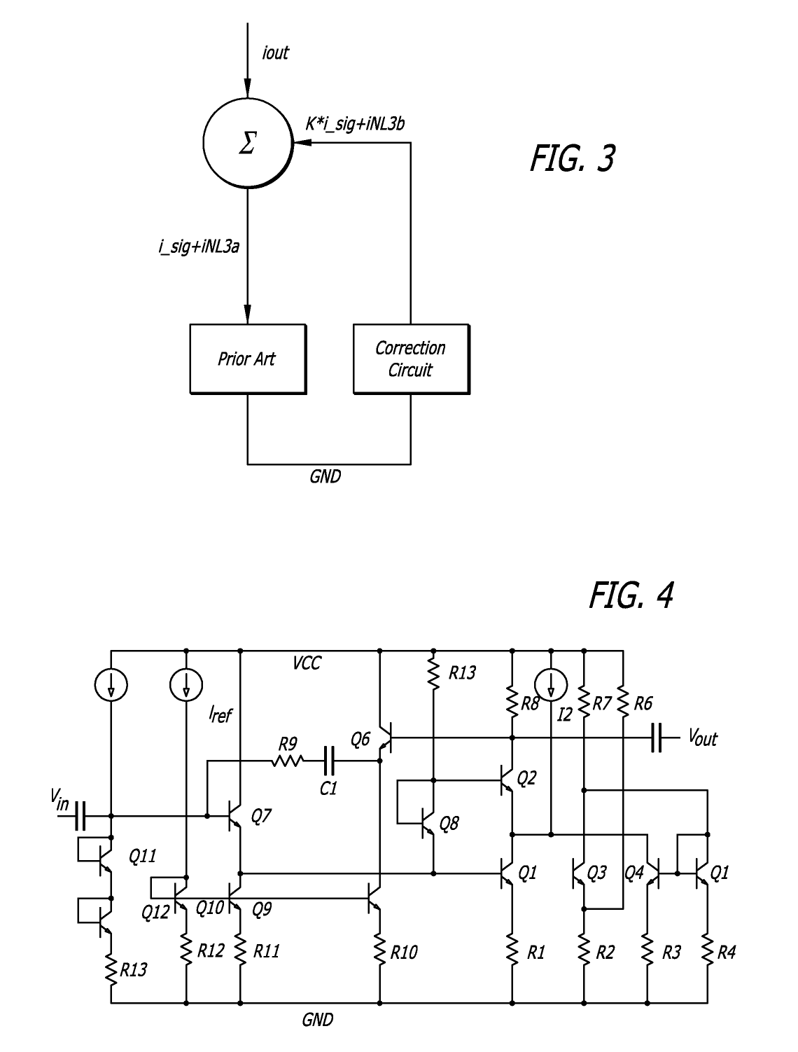

The concept of distortion nulling, which reduces the third order nonlinearities' contribution to the output signal without significantly increasing the DC current draw of the circuit, is presented in FIG. 3. The main amplifier, which is the prior art, generates a main signal current Δi and a third order nonlinear current I_{NL3a}, as described above. A novel correction circuit, which is added to the existing LNA according to the present invention, produces a scaled version of the main signal current kΔi, and a third order nonlinear current I_{NL3b} which is on the order of the nonlinear current in the main amplifier. The signal and nonlinear currents in the correction circuit are then directed through a current mirror circuit to be properly phased, and the output current of the mirror is then summed together with the currents in the main signal path. The resultant output current terms are:

Δi_{signal}=Δi−kΔi=(1−k)Δi where k is very small (<0.1-0.2)

I_{NL3(signal)}=I_{NL3a}−I_{NL3b}

Now, if the correction circuit is designed properly, the two nonlinear currents can be made close in magnitude and phase, such that an improvement in IM distortion by a factor of 2-10 is possible. A further challenge is to ensure that the correction circuit will work over process variations and temperature. It is also possible to have digitally programmable currents in the LNA to allow the current in the LNA to change as a function of process variations, and then these current settings would be required to work over the full temperature range for a given process variation.

A. Common Emitter (Bipolar/BiCMOS) Configuration

FIG. 4 illustrates a series-shunt feedback bipolar LNA, with IM correction circuitry used to implement the distortion nulling concept. This type of amplifier architecture is designed for a wideband match. This means that the input and output resistances are equal to approximately 50Ω over a wide range of frequencies. The input signal is applied to Q7 and is buffered to Q1. From Q7 to Q1 there is unity voltage gain. Q7 provides an isolation stage between the input terminal and the base current of the output stage transistor Q1. Q1 and Q7 need to be large area devices in order to achieve a low base resistance which results in lower input noise. The large area for Q1 introduces a large capacitance which can limit the output bandwidth of Q1. This capacitance is referred to as the Miller capacitance. In order to reduce the Miller effect and achieve high bandwidth, Q2 is connected above Q1. This configuration is referred to as cascode transistor. Emitter follower Q6 is provided to better isolate the feedback network from the output load resistor. R9 and C1, along with the gain of the amplifier, set the input and output resistance of this amplifier. This type of amplifier can be designed to have equal output and input resistances. A small value degeneration resistance R1 is applied in order to achieve linearity for the main amplifier stage. The addition of R1 allows for higher linearity since there is less VBE modulation across Q1. I2 is trickling current provided to give more voltage headroom for Q2, while reducing the distortion created in Q1 by increasing the current in that transistor. For the IM correction stage, Q3 taps off the base of Q1. The signal voltage at the base of Q1 generates signal current in Q3. This signal current is then pushed into Q5. Transistors Q5 and Q4 form a current mirror. Since Q5 is a diode connected transistor, the signal and the DC current in Q5 creates an equal VBE voltage across the two transistors Q5 and Q4. This VBE voltage will force Q4 to pull a current, equal to Q5's, from the Q1, Q2 connection. The mirror circuit of Q4 and Q5 provide a phase inversion for the signal and nonlinear currents created in Q3. This allows the correct signal currents to be summed into the Q1, Q2 connection. It is at this sum node where the signal current from the main amplifier stage and the signal current generated by the current mirror get summed. The summation of these signal currents produces a subtraction of nonlinear IM terms. It is particularly advantageous to sum the signals from the main stage and the IM cancellation stage at the connection between Q1 and Q2 since there is a small voltage swing at this intersection. There is a small voltage swing there as a result of the effective resistance at the intersection of Q1 and Q2. In order to achieve optimal IM cancellation, I3, the current in transistor Q3, and R2 have to be calculated in terms of I1 and R1, and the small signal parameters of both stages. The analysis of calculating R2 and I3, the current in transistor Q3, is shown below. As described previously, we want the I_{NL3a} nonlinear term of the main amplifier stage to be equal to the I_{NL3b} nonlinear term of the cancellation circuit in order to null the third order nonlinear terms. Since the bipolar LNA requires local degeneration in order for the cancellation to work properly, the G_{M} transconductance of the main and correction LNAs must be calculated taking this into account:

G_{M1}′=G_{M1}/(1+G_{M1}*R₁),G_{M2}′=G_{M2}/(1+G_{M2}*R₂)

We want the I_{NL3a} nonlinear term of the main amplifier stage to be equal to the I_{NL3b} nonlinear term of the cancellation circuit. Thus, for IM cancellation we want:

(G_{M1}′)(V_{T})(Δi₁/I₁)³=(G_{M2}′)(V_{T})(Δi₂/I₃)⁵

where
G_{M1} is the transconductance of the main bipolar device=I₁/V_{T},
G_{M2} is the transconductance of the correction bipolar device=I₃/V_{T},
Δi₁ is the signal current in the main bipolar device=G_{M1}′Δv_{IN},
Δi₂ is the signal current in the correction bipolar device=G_{M2}′Δv_{IN},
I₁ is the DC bias current in the main bipolar device Q1, and
I₃ is the DC bias current in the correction bipolar device Q3.

Now, using these definitions, and simplifying the equality:

(G_{M1}′)(G_{M1}′/I₁)³=(G_{M2}′)(G_{M2}′/I₃)³

Substituting for G_{M1}′ and G_{M2}′ and rearranging:

[G_{M1}/(1+G_{M1}*R₁)]⁴/(I₁)³=[G_{M2}/(1+G_{M2}*R₂)]⁴/(I₃₎³

But:

G_{M1}=I₁/V_{T} and

G_{M2}=I₃/V_{T}

so these relationships allow further simplification:

I₁/(1+G_{M1}*R₁)⁴=I₃/(1+G_{M2}*R₂)⁴

Now, I₁ and R₁ are set in the main amplifier design (i.e., the prior art). These values provide a base line distortion performance for the LNA. The variables for design are I₃ and R₂ and their values are limited to the constraints of the equation above. In FIG. 4, the applied DC voltage at the base of the main amplifier transistor Q1 is the same voltage applied to the transistor Q3 in the correction circuit. The collector current I₃ can be determined and this will allow the value of R₂ to be calculated as shown in the equation below, based on the above equation:

R₂=(I₃/I₁)^{1/4}*[(1+G_{M1}*R₁)−1]/(G_{M2})

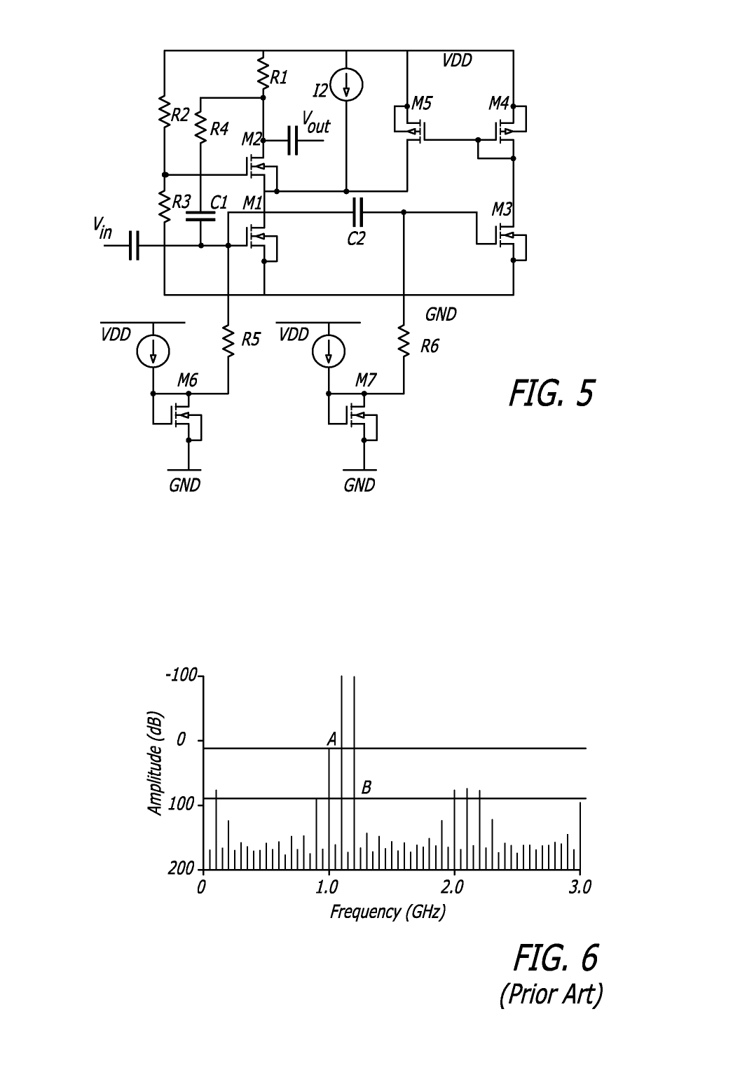

Now, based on the values of I₂ and R₂, the biasing of transistor Q3 in the correction circuit does not set up properly. This is because the DC base voltage for Q3 is fixed by the main LNA bias network. However, using the calculated value for R₂ in the circuit causes the DC current I₂ to be incorrect as a result of the applied DC bias voltage. Thus, an offset current source is required to be summed at the emitter of Q3. Summing in this current allows the correct value for R₂ and the proper current I₃ for the transistor Q3 to be realized. R6 in FIG. 4 provides this offset current such that Q3 has the correct DC current. Another way to provide for the proper biasing in the correction network is to have a separate bias network for the correction circuit transistor Q3, and AC couple the input signal to the correction network. An example of this implementation concept is shown for the CMOS LNA in FIG. 5.

B. Common Source (CMOS) Configuration

FIG. 5 illustrates a CMOS cascode amplifier with R4 and C1 in the feedback path. It should be noted here that there are many ways to implement the concept shown in FIG. 3, and FIG. 4 and FIG. 5 are only two such ways. This would be recognized by someone skilled in the art. Similar to the NPN LNA of FIG. 4, the CMOS LNA of FIG. 5 is a wideband match. The input and output resistances can be obtained by dividing R4 by the gain of the amplifier stage. This CMOS LNA uses a cascode configuration in order to achieve high output bandwidth and remove the channel length modulation effect on the main transistor M1. M2 is provided to remove the Miller effect and allow for large output bandwidth. R2 and R3 provide cascode device M2 with a gate bias voltage. In this configuration, the correction stage is composed of both NMOS and PMOS devices. Such use of both n and p type devices could not be implemented in the NPN LNA since typically PNP transistors exhibit low operating frequency range and poor current gain (Beta). However, if high frequency PNPs are available, then they could be used equivalently in the bipolar LNA. Also, care must be taken if PMOS devices are used in the mirror for the IM correction stage in the NPN LNA since PMOS transistors exhibit higher 1/f noise than bipolar transistors. The IM cancellation circuit starts with M3 tapping off the gate of M1 through an AC coupling capacitor C2. In this implementation, as described earlier, M3 has its own bias network. This allows the input signal to be coupled to the correction transistor M3, to generate the signal current, but does not force VGS of M3 to be the same as M1. Thus, the proper bias and aspect ratio (W/L) for M3 can be created in order to create the correct IM nonlinear terms. For the CMOS LNA, degeneration resistance is not required to generate the correction currents. Therefore, offset current sources cannot be used. This, then, puts too many constraints on the bias and aspect ratio of M3, thereby requiring it to have its own bias network. The signal current created by M3 is pulled down from M4 and creates a VGS across M4 and M5 in the mirror circuit created by M4 and M5. This VGS will force M5 to push the same signal current into the connection between M1 and M2. Again, the mirror circuit takes the signal and nonlinear currents from M3 and creates the proper phase for them to be summed into M1/M2. It should be noted that although the mirror is implemented using PMOS transistors, it can also be implemented with NMOS devices. The aspect ratio of the devices M4 and M5 must be sized properly so that the parasitic capacitance of the mirror does not affect the IM nonlinear current term created in M3. If it does, then the distortion nulling is not as effective, due to the added nonlinear current term created. Thus, the signal current generated by the correction stage gets summed with the signal current in the amplifier stage. Since the signal current generated by the IM cancellation circuit is out of phase with the signal current in M1, the result is the IM terms get subtracted from one another. Hence the circuit exhibits improved intermodulation distortion, which means that the amplifier has resultantly lower distortion. In order to calculate the aspect ratio and the current needed in M3, a Taylor series expansion of the MOS I-V characteristic must be performed. The detailed analysis is presented in “Frequency-Dependent Harmonic-Distortion Analysis of a Linearized Cross-Coupled CMOS OTA and its Application to OTA Filters” by J. Chen, E. Sanchez-Sinencio, and J. Silva-Martinez, IEEE Transactions on Circuits and Systems—I Regular Papers, Vol. 53, No. 3, March 2006. The results are summarized as follows for a single MOS device:

I_{NL3}=(G_{M})(Δv)/8(V_{DSAT}²)

where
G_{M} is the transconductance of the device=2(βI)^{1/2}
β=(μ_{N})(C_{OX})(W/L) for the MOS device
Δv is the signal voltage at the gate-source of the device
I is the DC bias current in the device
V_{DSAT} is the saturation voltage for the MOS device
V_{DSAT}=V_{GS}−V_{TH}

where V_{GS} is the DC gate-source voltage of the device, and V_{TH} is the threshold voltage of the device. Equivalently, V_{DSAT} can be written as:

V_{DSAT}=V_{GS}−V_{TH}

V_{DSAT}=I/β

Now, in order for the third order nonlinearity in M1 to be equal and opposite to the nonlinear term in M3, the third order nonlinear signal currents must be the same:

(G_{M1})(Δv³)/8(V_{DSAT1}²)=(G_{M2})(Δv³)/8(V_{DSAT}²)

Substituting in for the expression above, and canceling like terms, this simplifies to:

[(W₂/L₂)/(W₁/L₁)]³=(I₂/I₁)

Again, as with the bipolar LNA, (W₁/L₁) and I₁ are fixed for the prior art design. If one DC bias were used, then M3 cannot be designed properly, so a separate bias is used for transistors M1 and M3. Thus, once (W₂/L₂) is chosen, the equation above can be used to determine the correct DC bias current I₂ for M3 in order to provide the correct nonlinear signal current to cancel the nonlinear IM current created in the main amplifier.

As an example of the effectiveness of the distortion nulling, simulations have been performed for the CMOS LNA topology shown in FIG. 5, using the design equations presented. The two tone IMDs for input frequencies of 1.0 GHz and 1.1 GHz for the prior art base line LNA in FIG. 2 are shown in FIG. 6. The P_{OUT} of the fundamental tone is −13.5 dBm and the third order IM term is −91.8 dBm. In order to determine the output third order intercept for the LNA, the following equation is used:

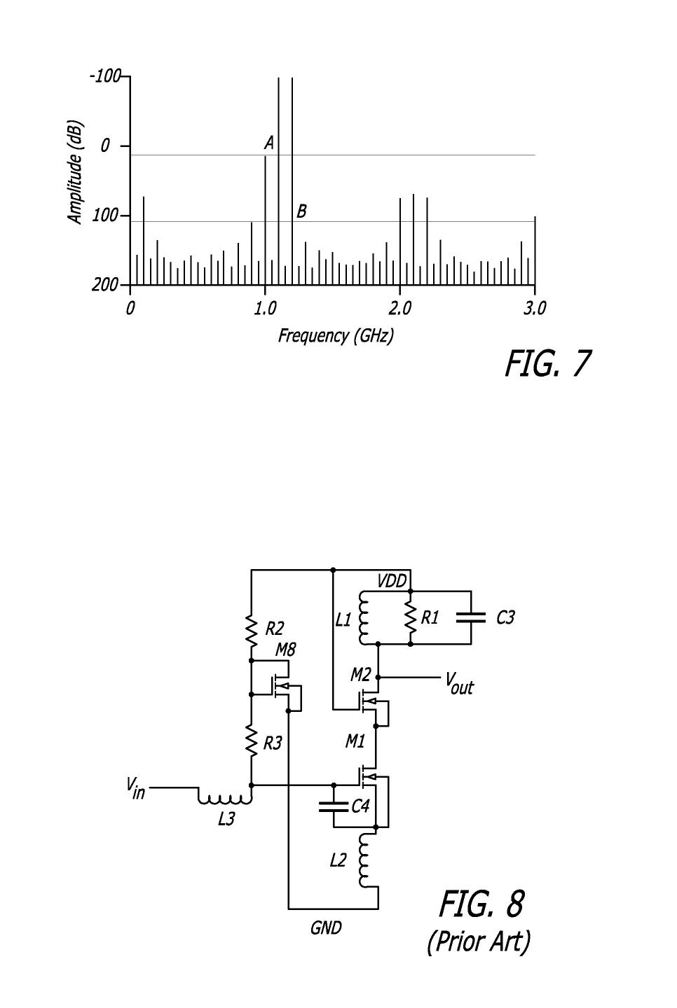

OIP3=[P_{OUT}+(SFDR/2)]dBm

where P_{OUT} is the output power of each of the two tones and SFDR is the spur free dynamic range for the LNA, or the Δ (in dB) between the fundamental tone and a neighboring IM term. Using the above expression, the OIP3 can be calculated to be 25.65 dBm for the base line, prior art LNA. A simulation result for the distortion nulling concept, implemented in FIG. 5, is shown in FIG. 7. From FIG. 7, the improved OIP3 is calculated to be 31.95 dBm, thus showing an improvement of 13.8 dB in SFDR over the existing prior art LNA. From the figure, as pointed out earlier, it can be seen that the power of the fundamental has been reduced by 0.6 dB, as a result of the fact that some of the main signal current is reduced as a result of the correction. This reduction in signal current is very small, relative to the benefits of the improved distortion performance.

The sensitivity of the effectiveness of the distortion nulling was investigated over process variations and temperature. Table 1 below summarizes the performance of the CMOS LNA of FIG. 5 at 1.0 GHz.

TABLE 1

| | Temperature | Prior Art OIP3 | With Distortion Nulling |
|---|---|---|---|
| Process | (° C.) | (dBm) | (dBm) |
| Nominal | 20 | 25.65 | 31.95 |
| Nominal | 80 | 24.66 | 28.6 |
| Slow | 80 | 25.3 | 27.8 |

Although it can be seen from Table 1 above that the error correction network for the distortion nulling is sensitive to process and temperature, the performance of the correction over process and temperature is still superior to the performance of the prior art for all conditions. As described previously, it is possible to maintain performance over process using digital calibration techniques in the correction stage. This allows the IM current cancellation to be maintained independent of process variations. Additional impacts of the distortion nulling correction circuit which should be considered include how well the correction holds up over frequency. With regards to device mismatches, the signal devices used in the main and correction circuits should be interleaved when routed in the layout. This will minimize the effect of device mismatch and resultant offset between the signal transistors in the main and correction circuits. With respect to frequency, any error correction circuit has finite bandwidth limitations, beyond which the correction network actually degrades the prior art performance. In other words, there is a point in frequency at which the LNA IM performance is better without error correction than with it. This is a result of phase shifts in the correction network. For many of the frequency ranges of interest for present radio applications, however, error correction can be taken advantage of to improve the overall LNA performance.

Thus, a distortion nulling concept has been developed, verified mathematically, and implemented. The concept can be applied to any process technology. It has been shown to be robust to temperature and process variations. It provides a solution to extend the dynamic range of future receivers without degrading the front end NF or DC power consumption.

II. Tuned Amplifiers

A. Tuned CMOS Amplifiers

The distortion nulling concept has been applied above to broadband amplifiers in the common source (emitter) configuration. The concept works equally as well for tuned amplifier designs. The application to tuned amplifier designs will be illustrate with reference to common base or common gate tuned LNAs.

FIG. 8 shows a prior art CMOS tuned amplifier. This is a common source LNA that uses inductive degeneration, an inductive input match, and an output inductive load that also acts as a DC choke. There are several advantages of this design approach. The first is dynamic range. The output load brings the drain connection of the cascode device to the rail, increasing both the DC and dynamic VDS of the device. This extra headroom allows for the consideration of potentially not needing a trickle current source, as is required in the broadband design. Additionally, the inductor in the source allows for degeneration impedance on the noise sources of the main transistor at the frequencies of interest, without the noise penalty of a real resistor. Also, there is no loss of DC headroom for use of this inductor. The inductor on the gate allows for a 50Ω impedance match at the frequency band of interest without the need for feedback, as is the case for the broadband design. Thus, there are many benefits of a tuned LNA design. One of the most important features is the noise figure (NF) achievable with a tuned LNA design. The drawback is that the gain response is a band-pass function, and all of the LNA parameters are “tuned” for a fairly narrow frequency band of interest, as opposed to the broadband design. Depending on the application, therefore, there may be a benefit to using one LNA topology over another.

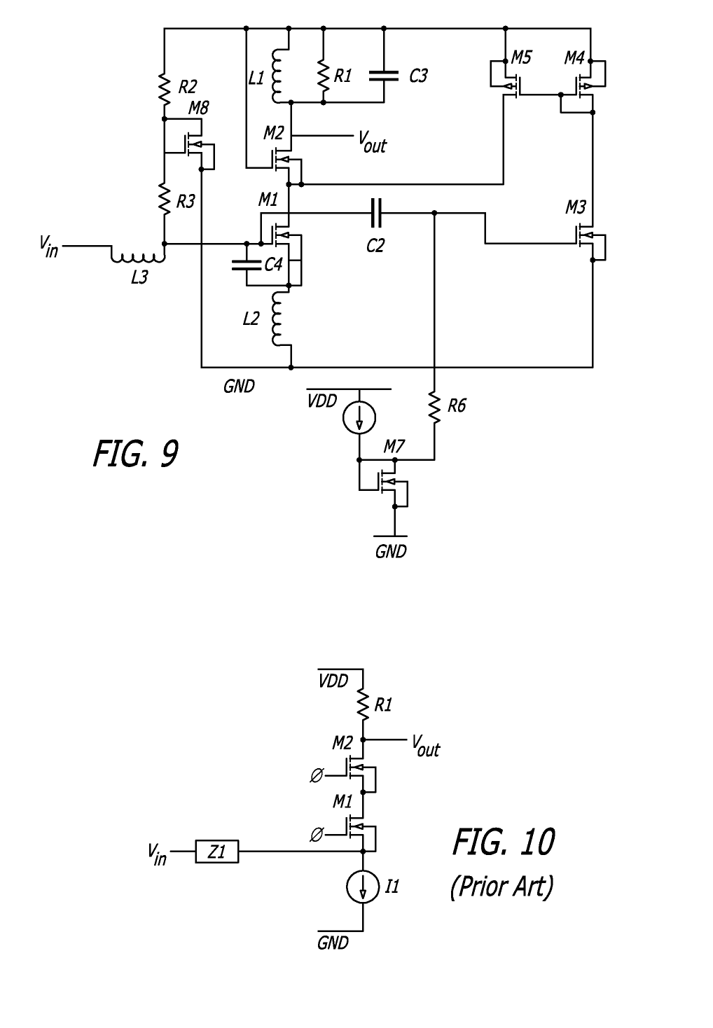

FIG. 9 shows a tuned amplifier provided with distortion nulling according to the present invention. The equations for the distortion correction network are the same as those developed for the broadband CMOS LNA.

Simulations have been performed on the prior art and the new corrected LNA to verify the performance. The design was tuned for a 2 GHz center frequency. At 2 GHz, the two tone OIP3 was simulated to be +21.1 dBm for the prior art LNA. For the corrected LNA, the OIP3 was simulated to be 26.1 dBm, producing a 10 dB increase in dynamic range for the intermodulation distortion products of the LNA. The NF at 2 GHz degraded slightly as a result of the added error correction, but this can be further improved by adding inductive degeneration in the correction network.

The concept of distortion nulling can be applied equally to a common gate (base) configuration as well as the common source (emitter) configuration. The prior art for this concept is shown in FIG. 10 for the broadband common gate configuration. Those skilled in the art can easily extend the concept to common base. In FIG. 10, the common gate amplifier can be designed in several ways. The input impedance can be set by the impedance looking into the source, or it can be set by a resistor, with the resultant source impedance of the transistor being very low impedance relative to the resistor value. Thus, the Z₁ in the prior art can either be a resistor or a capacitor, depending on how the input impedance is set.

Now, in FIG. 10, with an applied input voltage, there is a nonlinear voltage generated at the source of the common gate transistor as result of the device nonlinearity. Thus, assuming Z₁ is a resistor R₁, the resulting signal current into the source of the device can be written as:

Δi_{IN}=(V_{IN}−V_{NL3a})/R₁

where V_{NL3a} is the third order nonlinearity of the NMOS device.

Using the previous expression for I_{NL3a}, we can determine V_{NL3a}:

I_{NL3a}=(G_{M1})(Δv³)/8(V_{DSAT1}²)

I_{NL3a}=(G_{M1})(V_{NL3a})

Therefore:

V_{NL3a}=(Δv³)/8(V_{DSAT1}²)

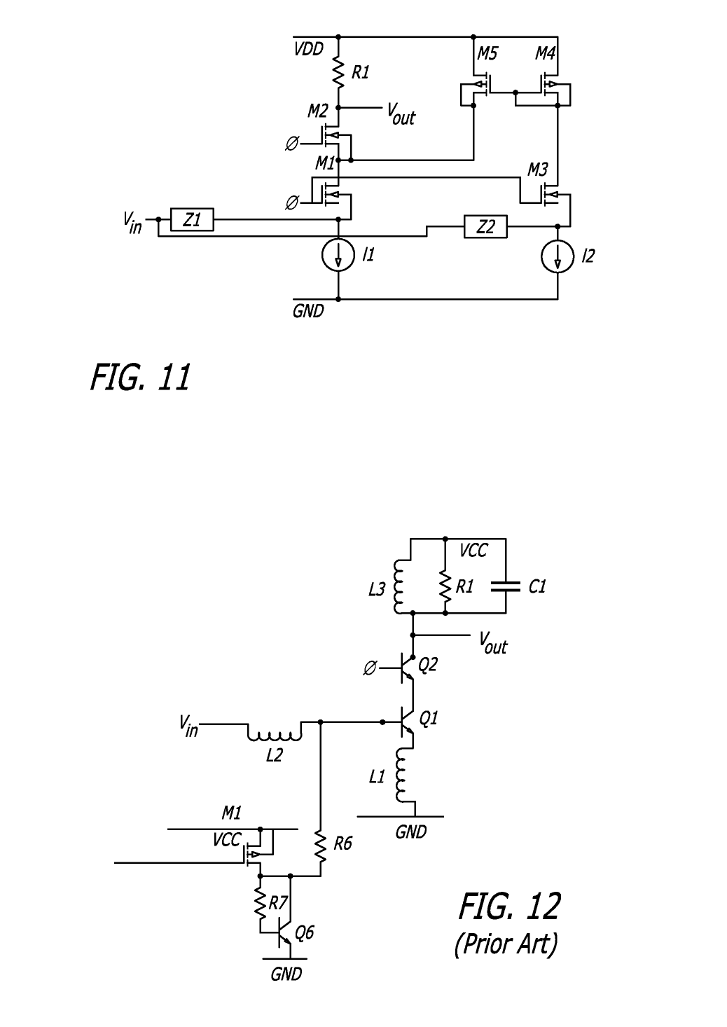

FIG. 11 is a schematic diagram showing the distortion nulling of the present invention applied to the common gate CMOS LNA. In the figure, for the correction network, if Z₂ is a resistor of value R₂, then in order for the correction network to work, it would require the following relationship:

V_{NL3a}/R₁=V_{NL3b}/R₂

and

V_{NL3b}=(Δv³)/8(V_{DSAT2}²)

Using the relationship

(V_{DSAT})²=I/β

we can simplify the equality to

(W₁/L₁)/(I₁R₁)=(W₂/L₂)/(I₂R₂).

The values for (W₁/L₁), I₁, and R₁ are already set in the prior art design. Thus, there is freedom to determine (W₂/L₂), I₂, and R₂ in the correction circuit. R₂ is determined by the amount of signal loss that will occur. Typically, as described earlier, that will be a few tenths of a dB. The prior art should have a (W₁/L₁) that is a multiple of the (W₂/L₂) for the correction circuit, created by using multiple parallel devices, each with an aspect ratio of (W₂/L₂). This will allow for the best tracking between main and auxiliary devices. This will then determine what I₂ is in order for the correction to work. This concept will also work for tuned common gate designs. This is well known by those skilled in the art, and it is a straight-forward procedure to apply the analysis to a tuned common gate LNA design, as was developed above for the common source amplifier.

B. Tuned Bipolar Amplifiers

In CMOS LNA applications, the transconductance of the device is low. This means that very large resistive degeneration is needed in order to improve the IP3 of the LNA. However a large resistive degeneration leads to a high noise figure (NF). For bipolar LNA's, the transconductance is much larger than the CMOS example. Hence, small values of resistive degeneration can be used to extend IP3 of the LNA without severely degrading the NF. Resultantly, a limitation of resistively degenerated bipolar LNA is the NF possible for a given IP3. The resistive degeneration generates Johnson noise which contributes to the overall NF. In some applications low NF (e.g., <2 dB) is desirable, which calls for a low value for degeneration, or no degeneration at all. Resultantly, a smaller degeneration resistor results in lower IP3 which can be fixed by increasing the DC power in the amplifier thereby increasing IP3. Increasing the DC power is undesirable for low power, low noise applications.

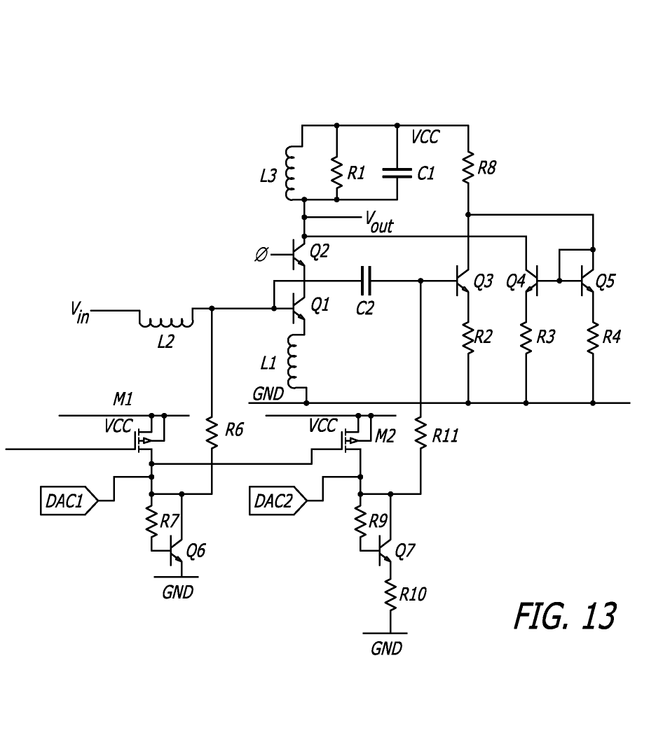

Another possibility, shown in FIG. 12, is to increase the degeneration to achieve higher IP3 and not sacrifice NF. The inductively degenerated bipolar LNA shown in the figure allows the noise to be low since the degeneration resistor is replaced with an inductor. Q1 and Q2 form the cascoded Common Emitter amplifier stage. L1 is the inductive emitter degeneration that has a real and imaginary resistance at the frequency of interest. At the frequency of interest, the magnitude of the inductance provides a noiseless degeneration for the transistor, which allow for higher IP3 without the DC power and noise penalty. L2 is provided to cancel the imaginary part of the input impedance created by L1. L3, C1, and R1 provide a resonance load at the frequency of interest. Q6 establishes a DC bias voltage for Q1. The input/output impedance is designed to be 50 ohms at a specified frequency. The architecture allows the noise to be very low at the expense of sacrificing dynamic range. The reason for this is without resistive degeneration the noise source is eliminated but the bipolar device is inherently nonlinear. By adding an inductor at the emitter of Q1, the magnitude of the impedance provides a noiseless degeneration at resonance. Although the noise is low for this tuned LNA, it would be desirable to improve the IP3 without increasing the DC power.

Thus, this is the motivation for the extension of the single ended distortion nulling concept to the tuned bipolar LNA shown in FIG. 13. The ideal way the correction stage would function would be to use a scaled version of the main inductor (L1) in the correction network. This would be an impractical solution for several reasons. One reason is since the correction stage is a scaled low power version of the main stage, the inductance needed in the correction stage would be an order of magnitude larger than L1. This inductance value would have a resonant frequency that is much lower in frequency than the resonant frequency of the main inductor L1. Hence, the solution is to use multiples of L1 to create the inductor in the correction stage. This is not practical either. Thus, the practical solution is to use a resistor in the correction stage and deal with the resulting issues, which are addressed in the text. As in FIG. 12, Q1 and Q2 form the cascode amplifier. L1 is the inductive degeneration; L2 cancels the imaginary part of the resistance created by L1. M1 and M2 are PFET current sources for the main and correction stage of the amplifier. Transistors Q3, Q4, and Q5 form the cancellation circuit used to cancel the IM terms created by Q1. It should be noted that Q4 and Q5 which form the mirror in the correction stage, must have a signal bandwidth on the order of the input signal bandwidth. If Q4 and Q5 have small bandwidths the phase of the correction stage will not be 180 degrees out of phase from the main stage. The result will be that the output IM terms will not optimally cancel each other. Hence the IP3 will not be as good as in the case where Q4 and Q5 have sufficient bandwidth. DAC1 and DAC2 are used to add or subtract DC current from the main and correction stages. The current trimming process is described below. R2 is the emitter degeneration of the cancellation circuit. R2 must be calculated in relation to DC biasing conditions and L1. The equation to determine the degeneration resistor value is given below. C2 is placed between the main and correction stages so that the correction stage could be independently biased. This is done so that DC current in Q3 can be varied independently of the biasing of Q1. Using a separate bias for the correction stage allows the degeneration resistor to be determined without the need for an offset current source tied to the emitter of Q3. The offset current source would be required if the correction stage was directly DC coupled to main stage. An offset current source is required if the correction stage is directly DC coupled to the main stage, as a result of the fact that one bias network would be used for both the main and correction stages, as opposed to using separate bias networks for each. Resultantly, the DC bias in the correction network would not be correct, since the correction stage is biased off of the same bias network as the input stage. Thus, the offset current source would be needed to properly bias the correction stage.

Using a resistive degeneration in the correction circuit creates some design challenges, specifically, getting the correction stage to function over temperature and process. The DC bias network can be designed to work over temperature, process variation, and devices mismatches. Another important practice is to use one type of resistor in the bias circuits and in the main and correction stages. Also the current density in the main and correction stages should be the same for proper tracking. There are cases in which the DC current in this circuit needs to be digitally trimmed in order to achieve higher IP3. In the case of voltage offsets or resistor mismatches, the current in the correction and the main stage must be digitally programmable. This programmability is achieved through a digital to analog converters (DACs) DAC1 and DAC2 shown in FIG. 13. A resistor mismatch can cause the correction stage to have a different current which can degrade the overall performance. Current trimming can be used to correct the DC current in the correction stage or trim out any voltage offset in the correction circuit in order for the correction stage to properly function. The programmable digital to analog converters therefore provide a programmable correction for voltage offsets or resistor mismatches in order to achieve higher IP3.

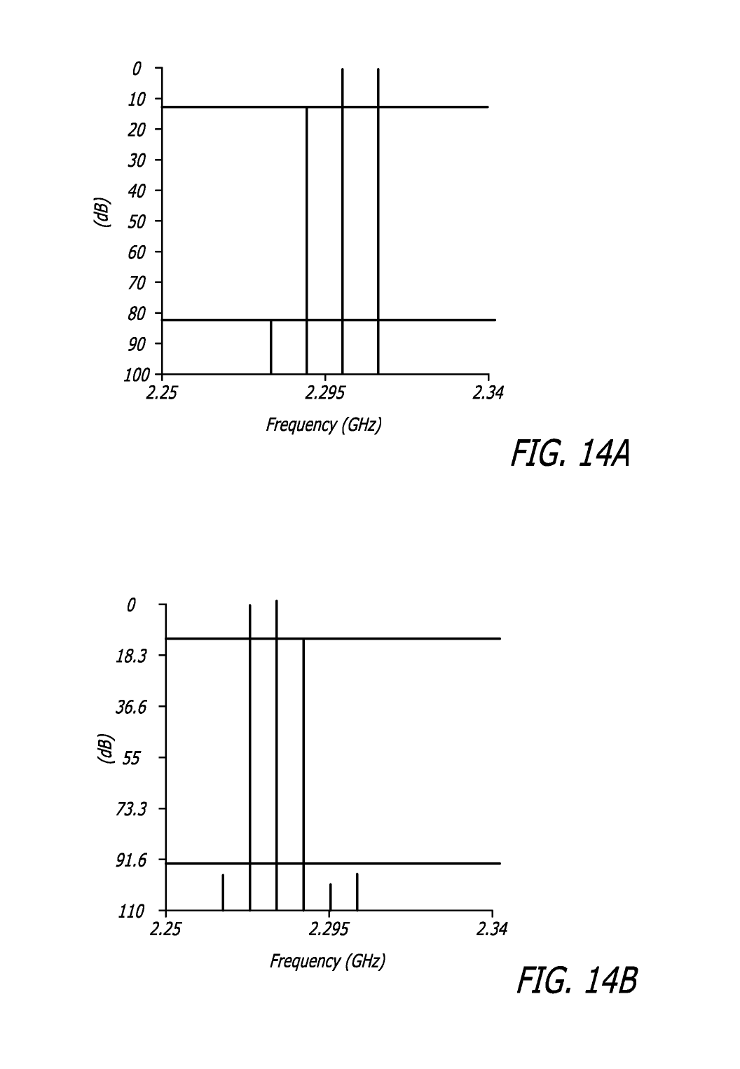

FIG. 14 shows a simulation that demonstrates this issue. In the simulation, a 2 mv offset was injected into the correction stage at the base of the correction transistor. The plot shows the effects of the offset and the result after trim current was applied. Process variations can also cause the correction stage to not function properly. Through simulations it can be shown that for the slow process case, more current is needed in the main stage of FIG. 13 in order to get optimal IM cancellation.

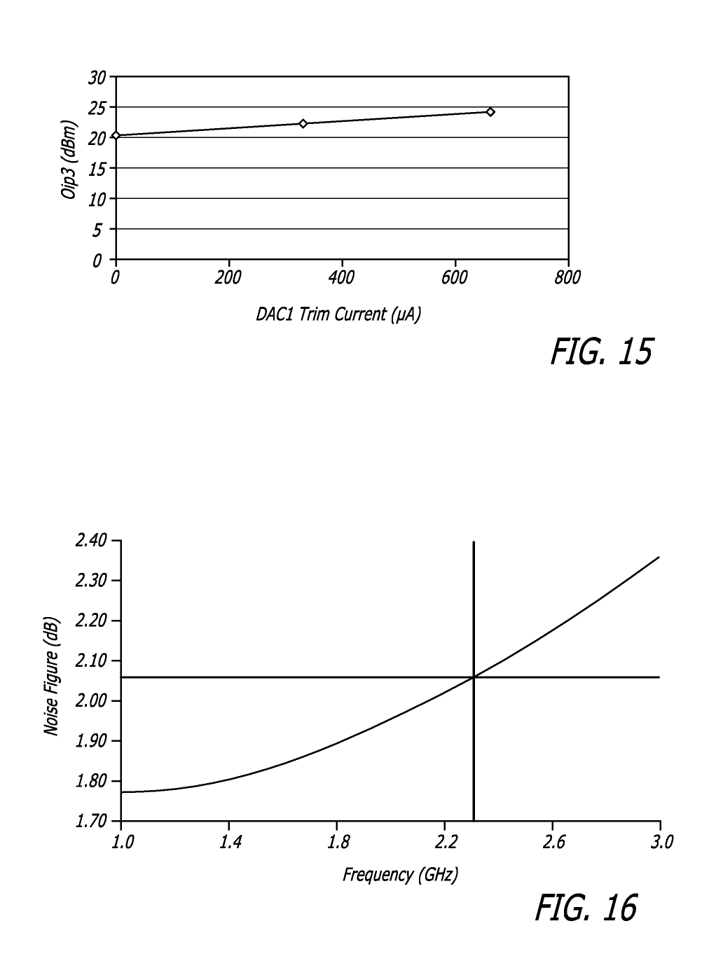

FIG. 15 shows OIP3 versus DAC1 trim current for the slow process. The current variation is achieved via DAC1 that adds or takes away DC current to the DC bias circuit that provides the DC operating point to the main stage. As stated above, low NF is also desirable.

FIG. 16 shows a noise floor for the circuit in FIG. 13, assuming a nominal process and a temperature of 27° C.

A significant limitation of the prior art solutions is that the prior art trades off performance for the noise versus dynamic range. Either one of these parameters is optimized at the expense of the other. All of the mathematics previously developed in the preceding sections applies to this section as well. The emitter degenerated inductor L1 has a real and imaginary part. In order for the correction stage to properly cancel IM terms, the magnitude of the L1's impedance must be related to the degeneration resistor R2 in the correction as:

R2=(I2/I1)^{1/4}*[((1+Gm1*ZL1)+1)/(Gm2)]

ZL1=Magnitude(2*π*f*L1) where f is the operating frequency.

In the corrected circuit of the present invention the issue becomes matching R2 to the magnitude of L1 over temperature and process. The bias in the main and correction stage should be optimized such that correction can be maintained over temperature. Simulations were run to analyze the OIP3 as a function of temperature at nominal process. These simulations, summarized in Table 2 below, demonstrated that for a nominal process, no trimming is needed to maintain OIP3 performance over temperature.

TABLE 2

| Temperature | |
|---|---|
| (° C.) | OIP3 (dBm) |
| 0 | 25.0 |
| 25 | 27.7 |
| 80 | 26.5 |

For other issues like process or device mismatch, it will be a requirement to have a digitally programmable current in order to maintain the distortion performance. This is accomplished through the use of a DAC to adjust the DC bias current in the correction stage or in the main stage. From the above equation, all the parameters except Gm2 are known. The proper current for the correction stage can therefore be calculated. It must also be noted that the mirror circuitry in the correction stage must have signal bandwidth on the order of the input signal bandwidth in order for the correction to properly cancel IM terms.

Table 3 below presents some of the simulation data for the performance of the circuit of FIG. 13.

TABLE 3

| Process | OIP3 (dBm) | Trim Adjustment |
|---|---|---|
| Nominal 27 | 27.8 dBm | No trim |
| Fast 27 | 27.5 dBm | No trim |
| Slow 27 | 20.3 dBm | No trim. |
| Slow 27 | 22.3 dBm | With +330 uA trim current added to main |
| | | stage (DAC2 trimmed only) |
| Slow 27 | 24.8 dBm | With +660 uA trim current added to main |
| | | stage (DAC2 trimmed only) |

From the table above, it is shown that even though the magnitude of the inductive degeneration does not track the resistive degeneration of the correction circuit over process, through current trimming the OIP3 can be maximized. Through simulations it was also shown that in the nominal and fast cases, current trimming was not needed when device mismatch was not considered. Thus the concept of single ended distortion nulling has been extended to the case of the inductively degenerated bipolar LNA. The extension of the single ended distortion nulling concept to the inductively degenerated bipolar LNA provides for unparalleled performance for NF and IP3 in the same architecture, when compared to the existing state-of-the-art performance in the industry.

It will be appreciated that the term “present invention” as used herein should not be construed to mean that only a single invention having a single essential element or group of elements is presented. Similarly, it will also be appreciated that the term “present invention” encompasses a number of separate innovations which can each be considered separate inventions. Although the present invention has thus been described in detail with regard to the preferred embodiments and drawings thereof, it should be apparent to those skilled in the art that various adaptations and modifications of the present invention may be accomplished without departing from the spirit and the scope of the invention. Accordingly, it is to be understood that the detailed description and the accompanying drawings as set forth hereinabove are not intended to limit the breadth of the present invention, which should be inferred only from the following claims and their appropriately construed legal equivalents.

We claim:

1. An amplifier circuit comprising:
a single-ended amplifier having a single-ended signal input and a single-ended signal output; and
a correction circuit comprising:
an auxiliary transistor having an input that is operatively connected to the amplifier;
a phasing section having an input that is operatively connected to the auxiliary transistor, the phasing section having an output that is operatively connected to the amplifier.

2. The amplifier circuit of claim 1 wherein said phasing section output is summed in said amplifier such that a phased version of the auxiliary transistor output is subtracted from a signal path of the amplifier.

3. The amplifier circuit of claim 1 wherein the phasing section comprises a current mirror.

4. The amplifier circuit of claim 2 wherein active components within said correction circuit consist of:
said auxiliary transistor; and
two transistors defining a current mirror, said current mirror defining said phasing section.

5. The amplifier circuit of claim 1 wherein said auxiliary transistor input taps off of a base of a common emitter stage which is coupled to a common base stage.

6. The amplifier circuit of claim 5 wherein said phasing section comprises a current mirror, said current mirror drawing a mirror current from a coupling point between said common emitter stage and said common base stage.

7. The amplifier circuit of claim 1 wherein a control voltage applied to a control terminal of a main amplifier transistor within said single-ended amplifier is equal to a control voltage applied to a control terminal of said auxiliary transistor.

8. The amplifier circuit of claim 7 wherein said control terminals are base junctions of bipolar transistors.

9. The amplifier circuit of claim 1 wherein:
said auxiliary transistor defines a scaled version of the amplifier and which produces an approximation of the third order intermodulation terms of the amplifier; and
said phasing section output is summed within said amplifier such that said third order intermodulation terms of the amplifier are substantially reduced.

10. The amplifier circuit of claim 9 wherein said substantial reduction consists of a reduction on the order of 10 dB.

11. The amplifier circuit of claim 1 wherein a degenerative resistance of said auxiliary transistor satisfies the equation:
R₂=(I₃/I₁)^{1/4}*[(1+G_{M1}*R₁)−1]/(G_{M2})
where:
I₁ is a DC bias current in a main transistor of said amplifier;
I₃ is DC bias current in said auxiliary transistor;
R1 is degenerative resistor of said amplifier;
G_{M1} is the transconductance of said main transistor; and
G_{M2} is the transconductance of said auxiliary transistor.

12. The amplifier circuit of claim 1 wherein said amplifier is a tuned amplifier further comprising inductors within said amplifier.

13. The amplifier circuit of claim 1 wherein said amplifier comprises bipolar transistors and is of a common emitter design.

14. The amplifier circuit of claim 1 wherein said amplifier comprises field effect transistors and is of a common source design.
